(19) United States
(12) Patent Application Publication
(10) Pub. No.: US 2018/0202964 A1
(43) Pub. Date: Jul. 19, 2018

(54) MODULAR CHEMIRESISTIVE SENSOR

(71) Applicant: Innosense LLC, Torrance, CA (US)

(72) Inventors: Maksudul M. Alam, Glendora, CA (US); Uma Sampathkumaran, Torrance, CA (US)

(21) Appl. No.: 15/851,587

(22) Filed: Dec. 21, 2017

Related U.S. Application Data
(63) Continuation-in-part of application No. 14/658,034, filed on Mar. 13, 2015, now Pat. No. 9,896,772.
(60) Provisional application No. 61/952,557, filed on Mar. 13, 2014.

(51) Int. Cl. G01N 27/327; H01L 51/00; G01N 27/12; C25B 3/00

(52) U.S. Cl. CPC G01N 27/3278; H01L 51/0021; H01L 51/0006; H01L 51/0035; H01L 51/0049; H01L 51/0093; G01N 2800/7028; C25B 3/00; G01N 2800/2821; G01N 2333/4709; G01N 2333/96433; G01N 2800/2835; G01N 2800/32; G01N 27/127

(57) ABSTRACT

The present invention relates to methods of forming modular chemiresistive sensors. The sensors preferably have two gold or platinum electrodes mounted on a silicon substrate with the electrodes connected to a power source and are separated by a gap of 0.5 to 4.0 μm. Functionalized polymer nanowire or carbon nanotube span the gap between the electrodes and connect the electrodes electrically. The electrodes are further connected to a circuit board having a processor and data storage, where the processor measures current and voltage values between the electrodes and compares the current and voltage values with current and voltages values stored in the data storage and assigned to particular concentrations of a pre-determined substances.

This application is a continuation in part of U.S. patent application Ser. No. 14/658,034, filed Mar. 13, 2015 which claims priority based on U.S. Ser. No. 61/952,557, filed Mar. 13, 2014, which is incorporated herein in its entirety.

This invention was made with government support under (1) Grant: DE-SC0008210—awarded by Department of Energy, Chicago, Ill., (2) Grant: 5R43AG029006, awarded by National Institutes of Health, Washington, D.C., and (3) Contract: HQ0147-13-C-7333—awarded by Missile Defense Agency (MDA), Redstone Arsenal, Ala.

### FIELD

The present invention relates to a modular chemiresistive sensor incorporating conductive polymeric nanowires or carbon nanotubes. In particular, a modular chemiresistive sensor for hypergolic fuel and oxidizer leak detection, carbon dioxide monitoring and detection of disease biomarkers.

### BACKGROUND

Missile systems, such as the Theatre High Altitude Area Defense (THAAD) ballistic missiles, use hypergolic fuels and oxidizers as a means of propulsion. These hypergolic propellants and oxidizers are corrosive, carcinogenic, toxic, and present fire hazards when a leak is present. Their storage and deployment are thus crucial to ensure personnel safety and mission success. The hypergolic fuel used in missiles is hydrazine or monomethyl hydrazine (MMH), and the oxidizer used in missiles is mixed oxides of nitrogen (MON-25) that is a mixture of dinitrogen tetroxide (N₂O₄), nitrogen dioxide (NO₂) and nitric oxide (NO). N₂O₄ is a dimer of NO₂. Under equilibrium conditions, nitrogen tetroxide (NTO) exists as a mixture of N₂O₄ and NO₂. Therefore, detection of MMH and NO₂ exterior of their storage vessels would indicate a leak in the system.

Electrochemical, chemiluminescence, chemical resistance, absorption, and fluorescence-based detection systems have been developed for the detection of hypergolic fuel and oxidizer leaks. However, these leak-detecting sensor devices suffer from drawbacks such as lack of specificity, less effective operation at elevated temperatures, and cell leakage problems leading to maintenance challenges. In addition, the prior art electrochemical monitoring devices can operate in the range −20° C. to +71° C. However, the response time of prior art electrochemical systems at −20° C. is typically 55 minutes at 100 ppm for NO₂, and their sensitivity is typically about 100 ppm for both MMH and NO₂. Prior art systems also should be replaced annually—which is a maintenance burden and drives system lifecycle costs. Thus, the development of a highly reliable and accurate transducer element to detect rapid changes in concentration of hypergolic fuels and oxidizers within a tactical leak detection subsystem is desired.

Atmospheric levels of carbon dioxide (CO₂) have risen significantly from pre-industrial levels of 280 ppm to present levels of 404 ppm. Predictions on future energy use indicate a continued increase of atmospheric CO₂ unless major changes are made in the way energy is produced and how carbon is managed. Due to current concerns about global climate change related to increased CO₂ emissions, efforts are underway to better utilize both terrestrial and geologic CO₂ sinks as forms of carbon management, offsetting emissions from fossil fuel combustion and other human activities. The storage of industrially generated CO₂ in deep geologic formations is considered a viable method and important for reducing CO₂ (green house emissions) from the atmosphere. Roughly a billion metric tons of CO₂ has to be sequestered annually to make an impact. The Department of Energy (DOE) carbon sequestration “Monitoring Verification and Accounting (MVA)” program requires sensors to monitor, measure and account for 99% of CO₂ in the injection zones to confirm safe and permanent storage of CO₂ in geologic formations, especially in the near-surface and subsurface environments over a large area with improved accuracy and long-term durability. Reliable and cost-effective monitoring systems are critical to safe permanent storage. Light Detection and Ranging (LIDAR) or satellite-based technologies are only effective for atmospheric or above ground CO₂ monitoring. By the time leaked CO₂ appears above the surface, significant damage may have occurred to ground water and the surrounding ecosystem. Therefore, a reliable and cost-effective near-surface/subsurface CO₂ monitoring system is critical to confirming the safe and permanent storage of 99% of CO₂ in the geologic injection zones.

Alzheimer's disease (AD) is the most common form of dementia. AD and other forms of dementia impose a tremendous financial burden on the health care system and the general economy. According to the Alzheimer's Association, the cost of caring for AD patients is estimated to be $203 billion in the United States in 2013. In addition, 15.4 million Americans provide unpaid care valued at $216 billion for persons with AD and other dementias. Unless addressed, the cost of AD is estimated to reach $1.2 trillion by 2050. Therapeutics can delay the onset of AD to an extent; however, their efficacy depends on early diagnosis. In 2012, the U.S. Food and Drug Administration (FDA) approved Amyvid™, a radiopharmaceutical imaging agent for positron emission tomography (PET) scans that measure the brain β-amyloid plaque density in-vivo in patients. The PET scans are highly sensitive. However, Amyvid PET scan is not a test for predicting the development of AD-associated dementia and is not intended to monitor patient responses to AD therapy. Amyvid does not replace other diagnostic tests used in the evaluation of cognitive impairment. In addition, PET scans are costly, time consuming, require skilled personnel, and cannot be used as a point-of-care application in doctor's offices and clinics. Another diagnostic method based on a flow cytometric test of Aβ phagocytosis for the detection of AD biomarkers in blood was reported. Neither of these approaches can easily be converted into a cost-effective diagnostic or research tool. Despite the utmost importance, no cost-effective biosensor technologies have been marketed to detect AD biomarkers. Therefore, there is an urgent need to develop technologies for AD screening and early presymptomatic diagnosis. Developing a simple and low-cost biosensor for reliable early diagnosis of AD in point of care facilities is needed.

Cancer is a group of diseases characterized by uncontrolled growth and spread of abnormal cells. It is the leading cause of death worldwide. The United States National Cancer Institute Society has estimated that there are 1,444,920 new cases of cancer and about 559,650 deaths in the United States each year—more than 1500 deaths per day. The National Institutes of Health estimates that the overall costs for cancer in each year are $206.3 billion: $78.2 billion for direct medical costs; $17.9 billion for indirect morbidity costs; and $110.2 billion for indirect mortality costs. This problem underscores the need for reliable and cost-effective methods for early detection and diagnosis of cancer. A device to monitor cancer therapy progress is also needed. There are several different kinds of cancer. For example: (i) Prostate cancer (PC) is the most common type of cancer found in American men. The American National Cancer Society estimates that there are 218,890 new cases of PC and 27,050 deaths in the United States in each year. PC is the second leading cause of cancer death in men in the United States. Prostate specific antigen (PSA) is the over-expressed biomarker of PC, and is crucial for the detection and diagnosis of PC. (ii) Breast cancer (BC) is the most frequently diagnosed cancer in women. The American National Cancer Society estimates that there will be about 240,510 new cases of breast cancer among women and, as estimated, 40,910 breast cancer deaths (40,460 women and 450 men) are expected in the United States each year. BC ranks second among cancer deaths in women. A protein called human epidermal growth factor receptor 2 (HER-2/neu) is overexpressed in about 20-30% of BCs, which tend to be more aggressive. This overexpressed HER-2/neu protein is an important therapeutic target/biomarker for diagnosis and prognosis of BC. (iii) Lung cancer (LC) accounts for the most cancer related deaths in both men and women. An estimated 213,380 new cases and 160,390 deaths, accounting for about 29% of all cancer deaths, are expected to occur in the United States in each year. Epithelial cell adhesion molecule (EpCAM) protein is an important biomarker of LC. A primary cause of poor survival rates is that many cancers are detected late, after they have spread or metastasized to distant sites. For most types of cancer, the earlier the detection the greater the chances of survival. Therefore, there is an urgent need for devices or methods that can accurately and reproducibly measure multiple cancer biomarkers or circulating tumor cells in bodily fluids or other specimens obtained by minimally invasive methods.

### SUMMARY

The present invention relates to a modular chemiresistive sensor. In particular, a modular chemiresistive sensor for detecting leaks of stored chemicals, particularly hypergolic fuel and oxidizer leak detection, carbon dioxide monitoring and detection of disease biomarkers. The sensor preferably has two gold or platinum electrodes mounted on a silicon substrate where the electrodes are connected to a power source and are separated by a gap of 0.5 to 4.0 μM. A polymer nanowire or carbon nanotube spans the gap between the electrodes providing an electrical connection between the electrodes. The electrodes are further connected to a circuit board having a processor and data storage capabilities, where the processor can measure current and voltage values between the electrodes and compare the current and voltage values with current and voltage values stored in the data storage and assigned to particular concentrations of a pre-determined substance, such as those listed herein, or a variety of other substances.

### BRIEF DESCRIPTION OF THE DRAWINGS

The present invention described herein will become apparent from the following detailed description considered in connection with the accompanying drawings, which disclose several embodiments of the invention. It should be understood, however, that the drawings are designed for the purpose of illustration and not as limits of the invention.

FIG. 1A is a photograph of a preferred lab set up to perform electro-polymerization.

FIG. 1B is a photograph of a small-volume electrochemical cell with electrodes dipped in monomer solution.

FIG. 2 shows an exploded view and an assembled view of a preferred embodiment of a polymer nanowire microelectronic detector (PNMD) and sensor housing.

FIG. 2A is a schematic of a preferred embodiment of a circuit diagram for the circuit board assembly in FIG. 2.

FIG. 2B is a second schematic of a preferred embodiment of a layout of the circuit board assembly in FIG. 2.

FIG. 3A is a schematic of a preferred embodiment of a PNMD sensor.

FIG. 3B is a schematic of the preferred embodiment of a PNMD sensor with a conductive material bridging the gap between electrodes.

FIG. 4 are chemical structures of electroactive aniline monomer (left) and amine functionalized 2-(2-aminoethyl) aniline (right) for generating conducting polymer nanowires for sensing MMH and NO₂.

FIG. 5 is a diagram representing a chemical reaction that decreases in conductivity of polyaniline as a result of the reducing nature of MMH.

FIG. 6 is a diagram showing a change in chemical structure and an increase in the conductivity of alkylamine functionalized polyaniline as a result of a reaction with NO₂, a strong oxidizing agent.

FIG. 7 is a diagram showing chemical structures of other conducting polymers that can be used for the formation of PNMD as an MMH and NO₂ sensor.

FIG. 8A is a graph of current voltage (I-V) curve of a sensor device before and after nanowire growth.

FIGS. 8B-D are SEM images of nanowires grown across a 2 μm gap between electrodes in a sensor.

FIG. 9A is a schematic of an embodiment of a portable handheld bio-sensor for point of care early diagnosis of disease.

FIG. 9B is a schematic of an embodiment of a sensor chip array and an enlarged single biochip used with the handheld bio-sensor of FIG. 9A.

FIG. 10 is a schematic diagram of a test setup to measure I-V curves of a nanowire sensor.

FIG. 11A is a graph of the response of a PNMD sensor to increasing NO₂ concentrations at room temperature. The arrow in FIG. 11A indicates the direction of change in signal.

FIG. 11B is a graph of sensor response as a function of NO₂ concentration up to 100 ppm. The error bards (where visible) indicate ±5% of the value. R² indicates the increasing value for the linear trend line.

FIG. 12A is a graph of I-V curves of the PNMD sensor with increased MMH concentrations at 23° C. The arrow indicates the direction of change in signal.

FIG. 12B shows change in sensor response as a function of MMH concentration up to 300 ppm. The error bars (where visible) indicate ±5% of the value. R² indicates the regression value for the linear trend line.

FIG. 13A shows a signal response versus time (V-t) plot for NO₂ sensing by a PNMD sensor tested with a breadboard device. The flat line at 1.5V indicates the base curve of the sensors when exposed to an N₂ (gas stream) alone. The other line graphs the sensor response to various concentrations of NO₂ (0 to 100 ppm) at 40° C.

FIG. 13B shows the percent change (triplicate measurements) in sensor response as a function of NO₂ concentration. The error bars (where visible) indicate ±5% of the value. R₂ indicates the regression value for the linear trend line.

FIG. 14A is a graph showing signal response versus time (V-t) plot for MMH sensing by PNMD sensor tested with a breadboard device. The flat line at 1.5V indicates the base curve of the sensors when exposed to N₂ in air alone.

FIG. 14B is a graph indicating the sensor response to various concentrations of MMH (0 to 300 ppm) at 40° C. The percent change (triplicate measurements) in sensor response as a function of MMH concentration. The error bars (where visible) indicate ±5% of the value. R2 indicates the regression value for the linear trend line.

FIG. 15A is a graph of PNMD performance detecting NO₂; FIG. 15B is a graph of showing response to MMH concentrations. These graphs emphasize the responses of NO₂ and MMH compared to the interfering gases at 0-100 ppm NO₂ (FIG. 15A) and 0-300 ppm MMH (FIG. 15B) response plotted with the response from the interfering gases.

FIG. 16A and FIG. 16B show the response graph as a function of CO₂ concentrations up to 10,000 ppm for two different nanowire sensors. Each point is the average of three measurements, and the error bars (where visible) indicate ±5% of the value. R₂ indicates the regression value for the trend line.

FIG. 17 is a graph of I-V curves of an anti-Aβ42-modified nanowire device exposed to PBS solutions in a solution with various Aβ42 concentrations.

FIG. 18 is a graph of current versus time plots of an anti-PSA-antibody attached nanowire biosensor exposed to PSA antigen with 0, 10 and 14 ng/ml;

FIG. 19 is a diagram of the chemical structure of functionalized biocompatible polypyrrole for biosensor use.

FIG. 20 is a diagram showing conjugation of an antibody to functionalized biocompatible polypyrrole.

FIG. 21 is a schematic diagram showing a testing device with enlarged views illustrating a polymer nanowire assembly with an PSA-AB antibody attached and the interaction of the antibody with corresponding disease biomarker antigen or protein for detecting disease.

FIG. 22 is a diagram showing a reversible interaction of CO₂ with alkylamine (R—H₂) conducting polymers to form a carbonate (R—NHCO2).

FIG. 23A and FIG. 23B illustrate efficient growth of polymer nanowires with a porous nano-network from 0.2 M aniline monomer in 0.4 M HNO₃ electrolyte solution where FIG. 23A is a graph showing an electrochemical voltage-time growth profile and FIG. 23B is a SEM image of the polymer nanowires formed.

FIGS. 24A and 24B are graphs showing the responses of polymer nanowire sensor devices fabricated from 0.2 M aniline in 0.4 M HNO₃ where FIG. 24A illustrates 10, 20, 50, 60, 80 and 100 ppm NO₂, and FIG. 24B illustrates 10, 50, 100, 200 and 300 ppm MMH.

FIG. 25 is an SEM image of CNTs incorporated within the 2 μm gap between microelectrodes in a sensor device.

FIG. 26 is a histogram showing the distribution of CNT diameters grown within the 2 μm gap between microelectrodes.

FIG. 27A shows calibration curves and FIG. 27B shows and a bar graph of sensor devices for Hg²⁺, Mn²⁺, Mg²⁺, Ca²⁺, and control (p<0.01 by t-test).

FIG. 28A shows I-V curves and FIG. 28B shows a calibration curve of a representative mercury sensor device including a control when exposed to varying concentrations of Hg²⁺ in water.

FIG. 29A is I-V curves from a representative biosensor showing the Aβ1-42 Ab-Ag response.

FIG. 29B is I-V curves from a control device to which no antibodies were attached exposed to same concentration of Ags in PBS as in FIG. 29A.

FIG. 29C is derivative curves showing the overall response of a biosensor to varying concentrations of Aβ 1-42 Ag in PBS.

FIG. 29D shows a derivative curve response of a control device with no Abs attached exposed to the same concentration of Ags. p=0.002 (t test) as in FIG. 29C.

FIG. 30A is a line graph and FIG. 30B is a bar chart showing the overall response of multiple biosensor devices to varying concentrations of Aβ 1-42 Ag in PBS wherein the lower curve in FIG. 30A represents the response profile of the Ab-conjugated devices to its corresponding Ags and the upper line represents the response of control devices (with no antibody conjugation) exposed to the same dilution series of Ags.

FIG. 31 is a bar chart summarizing the response profile of biosensor devices conjugated with AD-specific Abs and exposed to corresponding Ags in PBS.

### DETAILED DESCRIPTION

Various embodiments are described with reference to the drawings, wherein like reference numerals are used to refer to like elements throughout. In the following description, for purposes of explanation, numerous specific details are set forth in order to provide a thorough understanding of one or more embodiments. However, such embodiment(s) may be practiced without these specific details.

In the following paragraphs, the present invention will be described in detail by way of example with reference to the attached drawings. Throughout this description, the preferred embodiments and examples shown should be considered as exemplars, rather than as limitations on the present invention. As used herein, the “present invention” refers to any one of the embodiments of the invention described herein, and any equivalents. Furthermore, reference to various feature(s) of the “present invention” throughout this document does not mean that all claimed embodiments or methods must include the referenced feature(s).

As used herein PNMD will be used to refer to a polymer nanowire or carbon nanotube microelectronic leak detector that uses an innovative sensing technology for sensitive and accurate detection gases, particularly MMH and NO₂ under dry nitrogen. The term PNMD will generally be used herein to refer to embodiments of a sensor, though not always for detection of hypergolic leaks. As will be shown, the sensors can be configured to detect other substances.

Miniaturized and low-power consuming PNMDs are fabricated by direct and site-specific growth of polymer nanowires (or carbon nanotubes) at patterned microchannel electrode junctions. The nanowires are preferably grown from electroactive aniline and functionalized aniline monomers (FIG. 4) using a template-free electrochemical method to form porous, electrically conductive filaments.

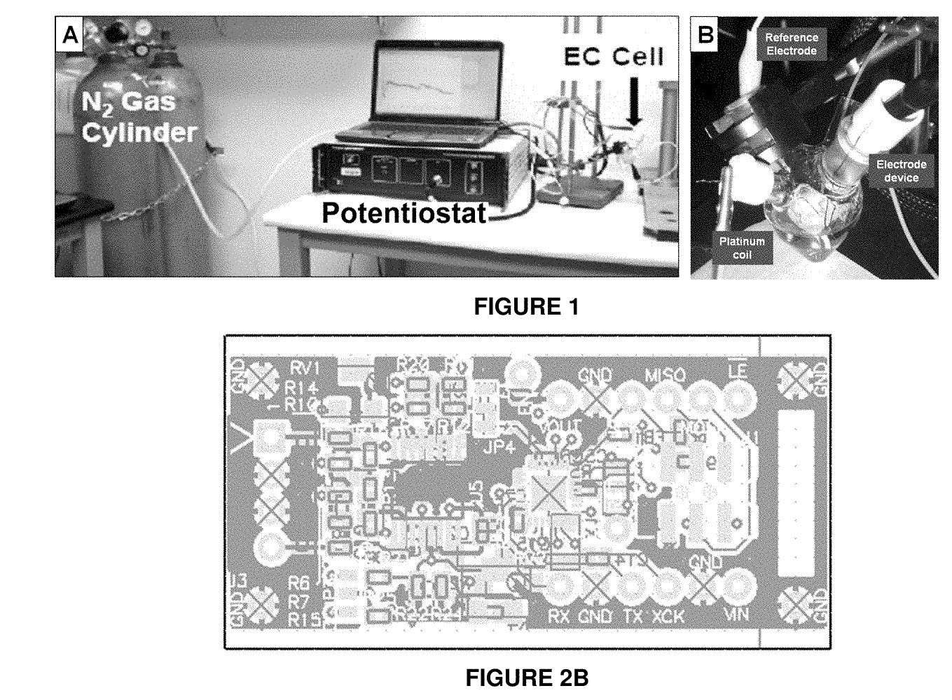

Referring now to FIG. 1, a preferred lab set up for direct electrochemical growth of polymer nanowires in a gap between two electrodes is shown. Preferably, an aqueous solution of an electroactive monomer in 1.0M nitric acid, perchloric acid or hydrochloric acid is used to generate the conducting polymer nanowires. A concentration of a monomer is preferably varied from 0.1M to 0.5M to generate different densities of nanowires. A small volume flask is filled with approximately 16 ml of monomer solution in which a wire-bonded electrode junction device is submerged. One side of the device acts as the working electrode. For a counter electrode a platinum coil is used. The platinum coil preferably has 10-12 turns and a wire diameter of 0.25 mm. A silver/silver chloride reference electrode is preferably used to monitor the reaction voltage. The solution is preferably purged with nitrogen for ten minutes prior to starting the electrochemical reaction. Nitrogen is constantly flowed into the flask during the evacuation to maintain a neutral and non-oxidative environment above the solution. An oxidative potential is applied to one side of the electrode junction device, and the platinum coil is grounded. A potentiostat system (e.g. Princeton Applied Research model 263A-1 potentiostat/galvanostat) is preferably used to provide the potential difference. This method oxidizes the monomers and triggers a chain reaction resulting in the formation of polymer nanowires.

A variety of substances can be used for, or in place of, nanowires including carbon nanotubes, graphene nanofilms, silicon nanowires, tin nanowires, titanium nanowires, metal oxids (zinc, magnesium, calcium, manganese, titanium, tin, and copper oxide) nanowires and nanotubes, graphene, and quantum dots. These various substances can then be used for chemiresistive microelectronic sensing applications.

The PNMDs' sensitivity to both MMH and NO₂ was tested. The PNMDs were tested for stability, sensitivity, response time, and temperature dependence from −46° C. to +71° C. PNMDs exhibit the ability to detect and distinguish 10-300 ppm of MMH and 10-100 ppm of MON-25 within 10 minutes. PNMDs are resistant to interfering gases such as oxygen, carbon dioxide, methane, acetone, alcohol (methanol), and water, with only a slight sensitivity to ammonia. PNMDs show promising stability to shock, vibration and long-term testing. A small footprint PNMD with electronic circuitry preferably provides calibration-free operation, eliminating drift and the effects of temperature and humidity. PNMD is suitable for integration with missiles, highly reliable detection of MMH and NO₂, an effective early warning system for trace detection of hypergolic fuel leaks with resistance to trace interferents, vibration and mechanical perturbations. PNMDs are also suitable to operate under a wide range of temperatures and environments.

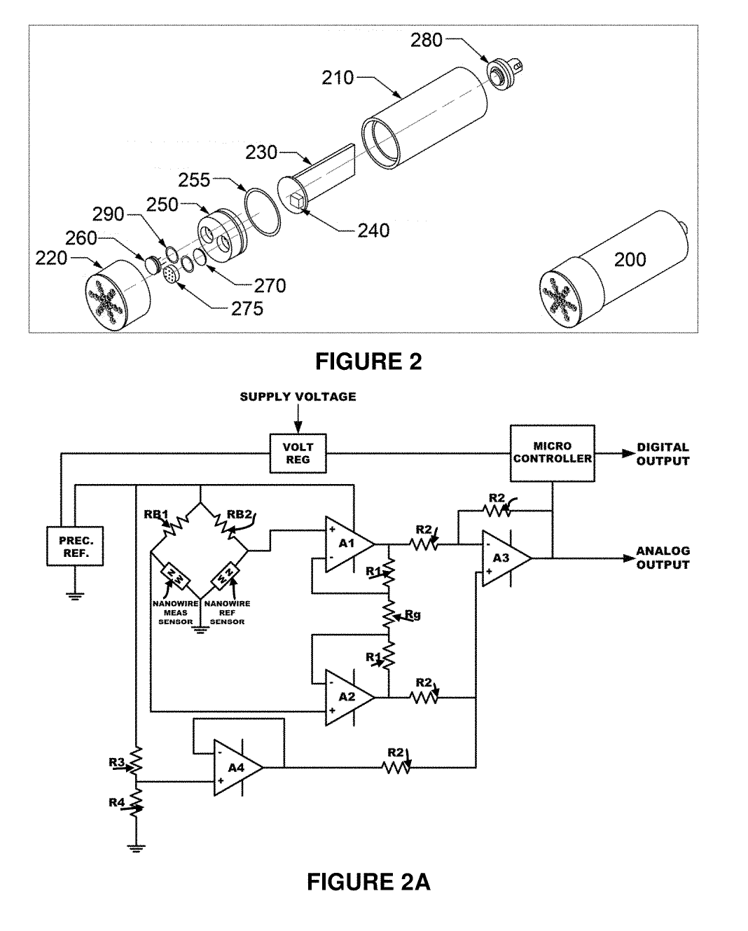

Referring to FIG. 2, an exploded view of a preferred embodiment of the sensor assembly 200 for the PNMD is shown. The sensor assembly preferably has a main housing 210 and a protective cap 220 to contain a circuit board assembly 230 with a PNMD sensor (or array of sensors) 240 mounted thereon. A sensor insert plug 250 and O-ring 255 preferably separate the PNMD sensor 240 and circuit board assembly 230 from a temperature sensor 260. The sensor insert plug 250 preferably comprises a member 270 and membrane retainer 275. A MIL standard connector 280 is mounted to housing 210 to connect the sensor assembly 200 to data and/or power sources (not shown).

FIGS. 2A and 2B show schematics of the preferred embodiment for the circuit board assembly 230. In FIG. 2A, the circuit 230 used for the nanowire sensors has a balanced bridge design with one sensor for reference and a second one for measurement. The bridge is formed by two nanowire sensors 240 and two precision resistors (RB1 and RB2). These fixed resistors are by design nearly equal to the room temperature resistance of the nanowire sensors. A precision 3-volt reference source drives the bridge. This voltage source is powered by a voltage regulator to minimize the dependency on the supply voltage. A differential voltage is formed at the two nodes of the bridge, which are connected to an instrumentation amplifier formed by amplifiers A1, A2 and A3. The gain of the instrumentation amplifier is controlled by a single resistor, Rg, and is equal to G=1±(2R1/Rg). Initially, the gain (G) of this circuit is set to 1 due to the high sensitivity of the nanowire sensors to the presence of the gas.

Although resistors RB1 and RB2 are selected to balance the bridge as well as possible, there is inevitably some small residual differential voltage. The nominal output of the instrumentation amplifier can be set by adjusting the offset input that is supplied by amplifier A4. This is a unity-gain buffer amplifier that sets the offset voltage based upon the resistive divider formed by R3 and R4. This resistive divider is driven by the precision reference source so that the offset will track any small changes in the reference source as temperature is varied. The final output of the instrumentation amplifier is provided as an analog output for data logging purposes. It is also provided to the input of an ADC within the on-board microcontroller, where it can be digitized, processed, and sent out through a serial communication port. The entire circuit is designed on a circuit board 230 that preferably measures 0.9 in.×1.7 in., which includes space for some connectors in order to make the testing more convenient. FIG. 2B shows the layout of main circuit board.

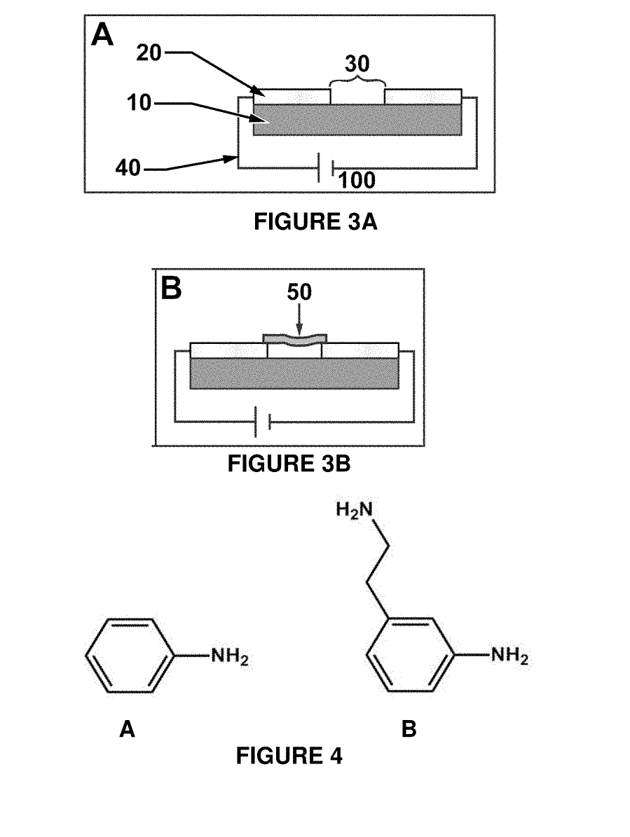

Referring now to FIG. 3, a schematic of a preferred embodiment of a PNMD is shown. This preferred embodiment has at least two electrodes 20 mounted on a cleaned silicon substrate 10. A preferred method of cleaning the substrate comprises placing the substrate in a 1% solution of an alkaline cleaning solution, preferably Micro-90® (International Products Corporation, Burlington N.J.) which is a concentrated, proprietary composition of chelating detergent that contains ionic and non-ionic ingredients, and applying ultrasonic energy for about 10 minutes. The cleaning solution is then replaced successively by solutions of DI water, isopropyl alcohol, acetone and DI water, with sonication of each solution, exposure for about 20 minutes to a Piranha Solution (7 parts H₂SO₄ to 3 parts H₂O₂) followed by copious rinsing with DI water and storing the cleaned silicone substrates in DI water.

Electrical leads are bonded to the electrodes and the connection is encapsulated by an epoxy material to protect it from the electrochemical process. The electrodes 20, preferably made of a noble metal such as gold or platinum, are placed on the cleaned silicon substrate in the electrolyte bath separated by a gap 30 of 0.5 μm (500 nm) to 4.0 μm (4000 nm), preferably about 2.0 μm (2000 nm) and are connected to a power source 100 by leads or wires 40. The assembled substrate and electrodes in the electrolyte bath is then purged and blanketed by a N₂ atmosphere. Electrical energy is then applied to the electrodes starting at about 0.7-0.8V. The process results in the electrodes 20 being electrically connected by a polymer nanowire or carbon nanotube 50 of diameter 30-150 nm and length 2-10 μm which are electrochemically formed, depending on the bath composition.

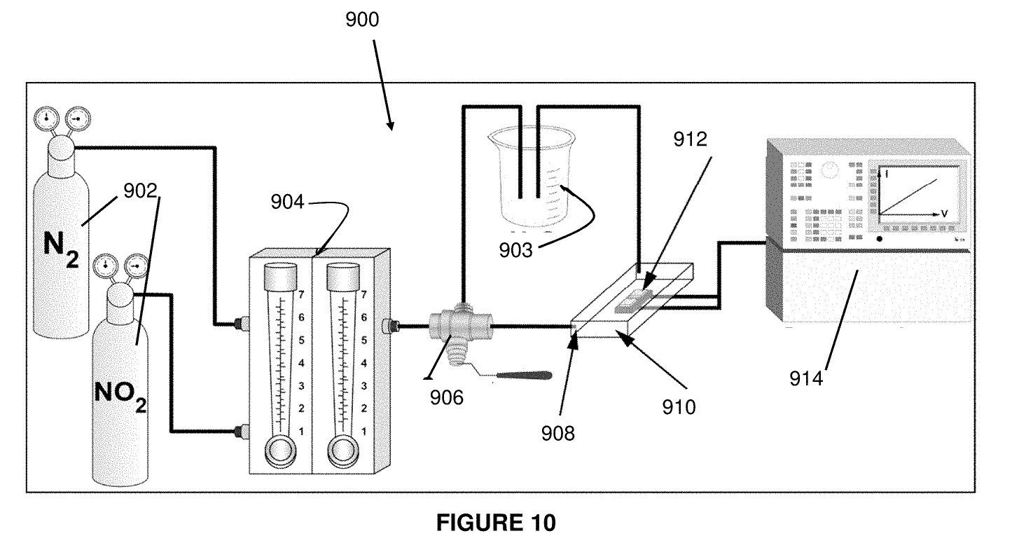

The simplest configuration of the nanowire sensor is a resistive junction composed of two solid state electrodes between which conducting polymer materials are grown. FIG. 10 shows a schematic test setup for measuring I-V curves of a nanowire sensor 900 which includes a gas supply 902, a water supply 903, gas mixers 904, a 3-way valve 906 connected to a gas inlet 908 of a test chamber 910. The sensor device 912 to be tested is connected to a semiconductor parameter analyzer 914 and placed in the test chamber 910. The electron transport properties of the sensor change upon exposure to analytes such as CO₂, MMH, NO₂ or bio-molecules. The equilibrium driven analyte binding interactions (van der Waals and/or dipole-dipole in nature) with nanowires change the electronic density and current flow of nanowires. The current-voltage curves of a nanowire sensor are measured before and after exposing the sensor to a target analyte (CO₂, MMH, NO₂ or biomolecues). The change in conducting current (before and after) of the nanowire sensor is directly proportional to the concentration of the exposed analyte. Therefore, by measuring the change in conducting current before and after the sensor is exposed to an analyte, the concentration of the target analyte can be determined. This calibration can be stored locally in the sensor assembly or in some other storage medium for later look-up.

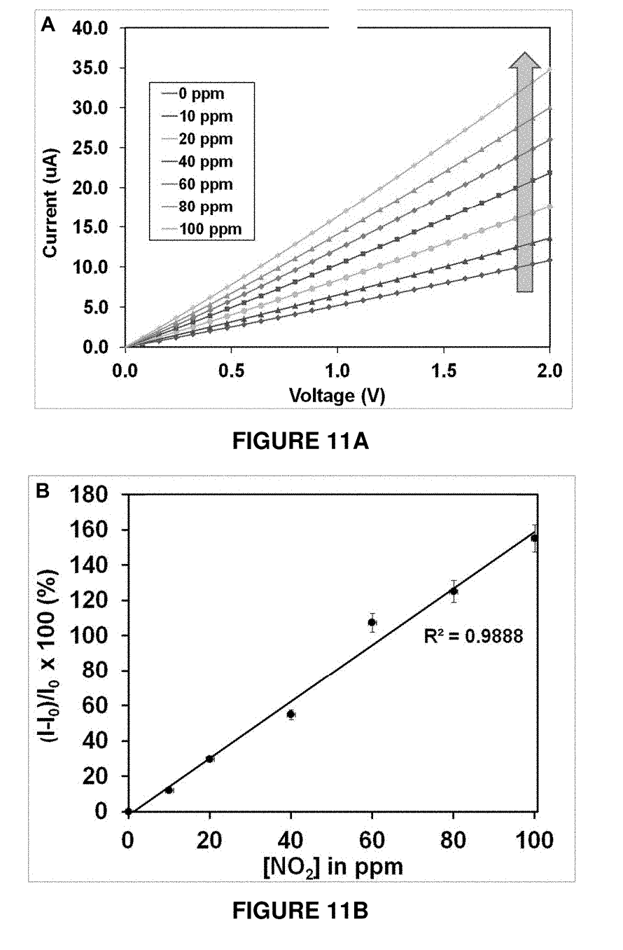

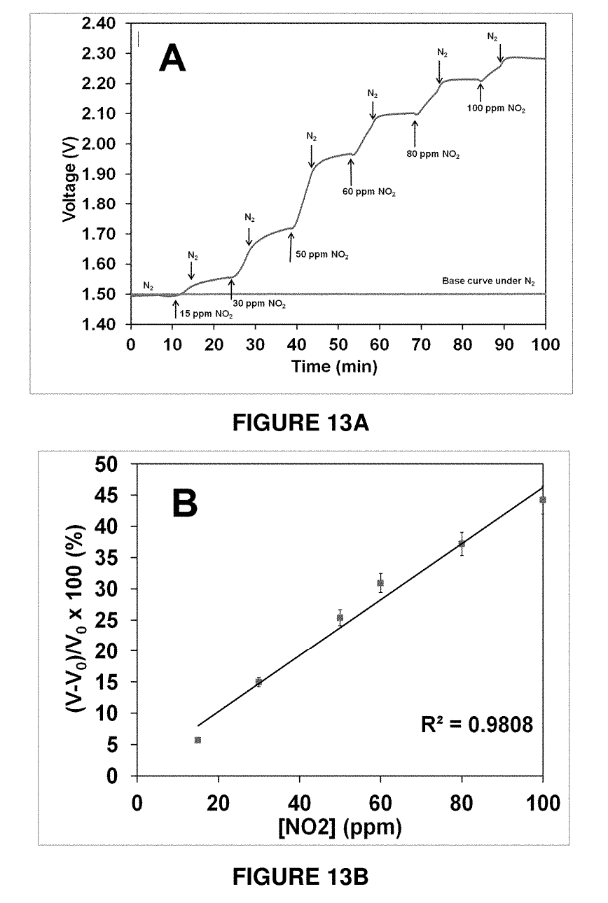

PNMD sensors in the presence of MMH and NO₂ at temperatures of −46° C., 0° C., 23° C., 40° C. and 71° C. in dry nitrogen (N₂) were tested. First, the PNMDs were tested for detecting NO₂ gas. The sensor signal responses were measured as current-voltage (I-V) curves and voltage-time (V-t) plots with an Agilent semiconductor parameter analyzer and a breadboard device (FIGS. 11 and 13). The I-V curves plotted with the Agilent semiconductor parameter analyzer showed that the PNMDs responded significantly when exposed to NO₂. The device current increased in positive direction with increasing NO₂ concentrations (0-100 ppm) and followed a linear trend line. Similar sensor response behavior was observed at all measured temperatures.

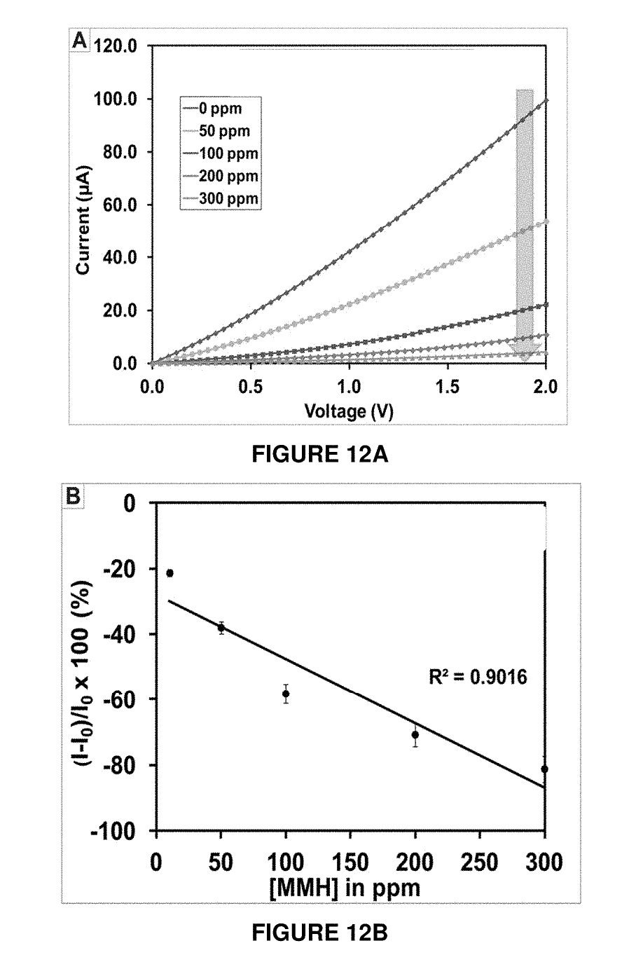

FIG. 12A shows I-V curves for detecting MMH at 23° C. measured with an Agilent semiconductor parameter analyzer. The PNMDs show significant response when exposed to MMH, and the device current decreased linearly as the concentration (0-300 ppm) of MMH increased (FIG. 12A) and followed a linear trend line (FIG. 12B). Similar sensor response was observed at other measured temperatures mentioned above.

FIG. 13 shows a representative voltage-time (V-t) plot measured by using a breadboard device at 40° C. for sensing NO₂. FIG. 13B shows that PNMD response increased to positive direction with increasing NO₂ gas concentration (0-100 ppm) due to oxidizing nature of NO₂. Similar NO₂ sensing responses were observed for the PNMDs at all measured temperatures.

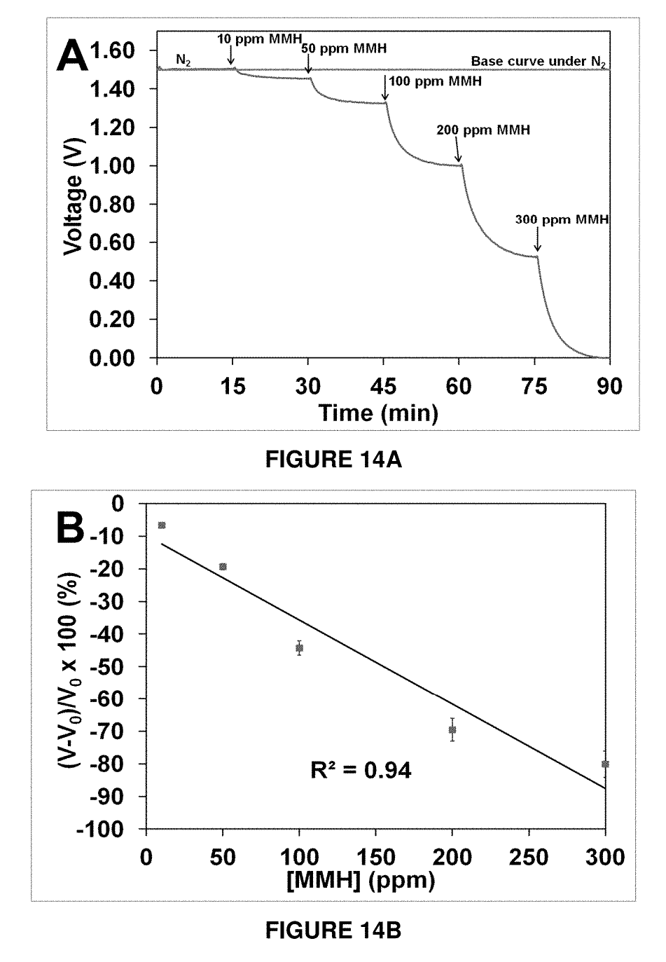

For sensing MMH (0-300 ppm), the sensor response (V) increased to negative direction with increasing concentration of MMH because of the reducing nature of MMH. FIG. 14 shows a representative V-t graph and a linear trend line plot at 40° C. for sensing MMH. Similar MMH sensing responses were observed for the PNMDs at all measured temperatures.

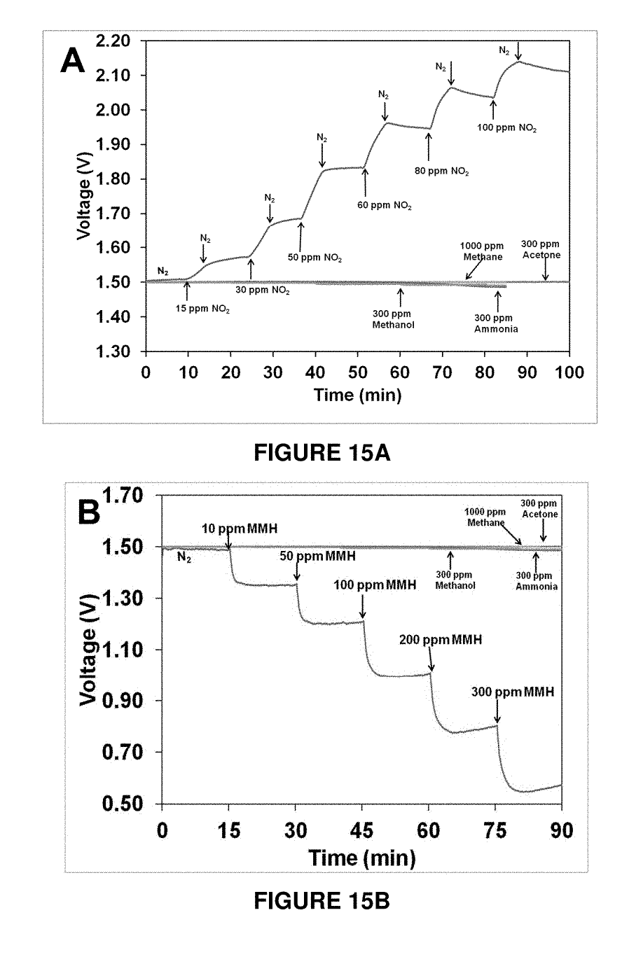

PNMD sensors can indicate trace leaks (≤50 ppm) of both MMH and NO₂ within minutes (<5 minutes) with high reliability, minimal cross-sensitivity, and minimal response to trace interference gases (FIG. 15). PNMDs show very promising long term operational stability (measured over six months), shelf-life, and tolerance to shock, and vibration.

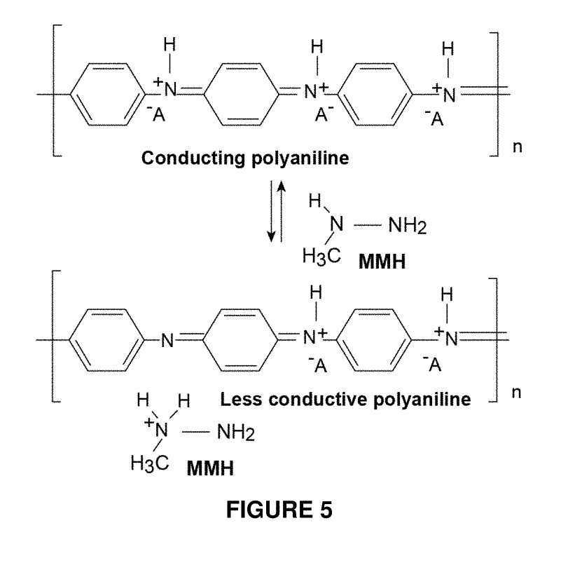

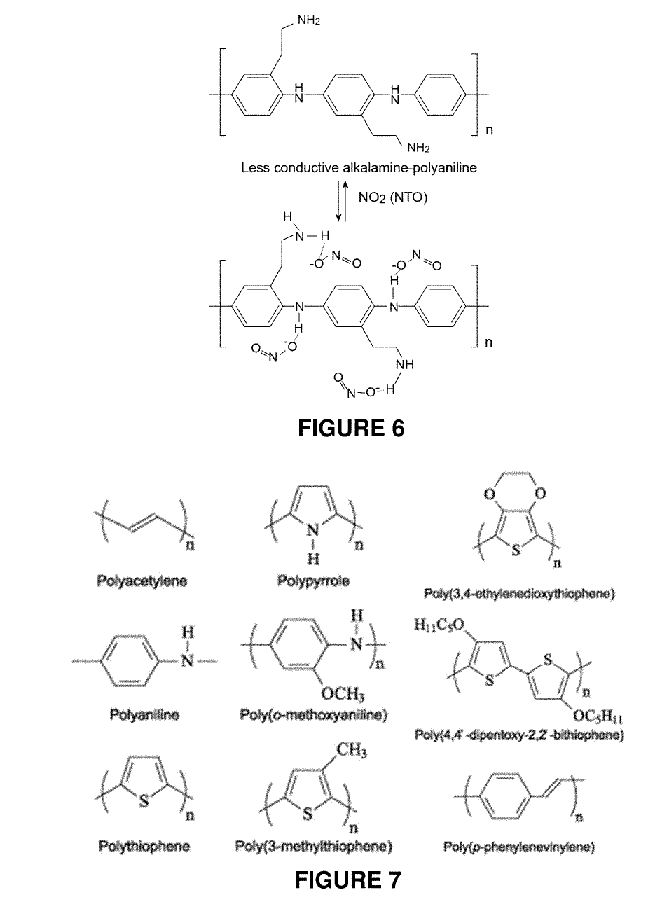

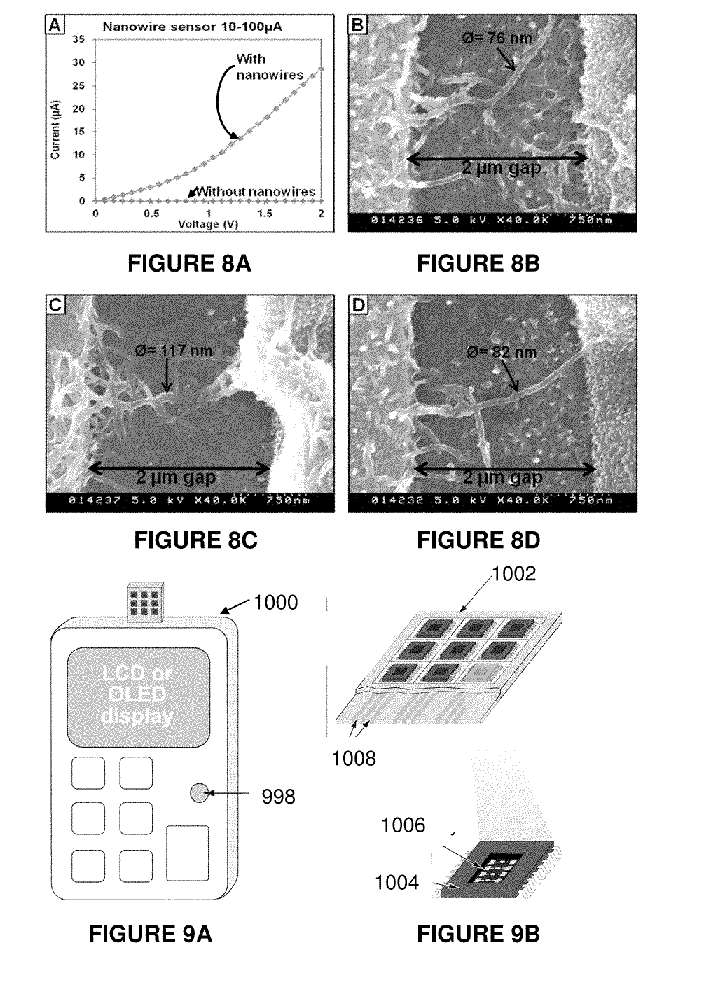

Chemical structure of polyaniline and its interaction with MMH are shown in FIG. 5. In this figure, the polyaniline is used to detect MMH. FIG. 6 shows the chemical structure of functionalized polyaniline and its interaction with NO₂. The novel process for the growth of polymer nanowires and the fabrication of both MMH and NO₂ sensors described herein was used.

Carbon Dioxide (CO₂) Monitoring.

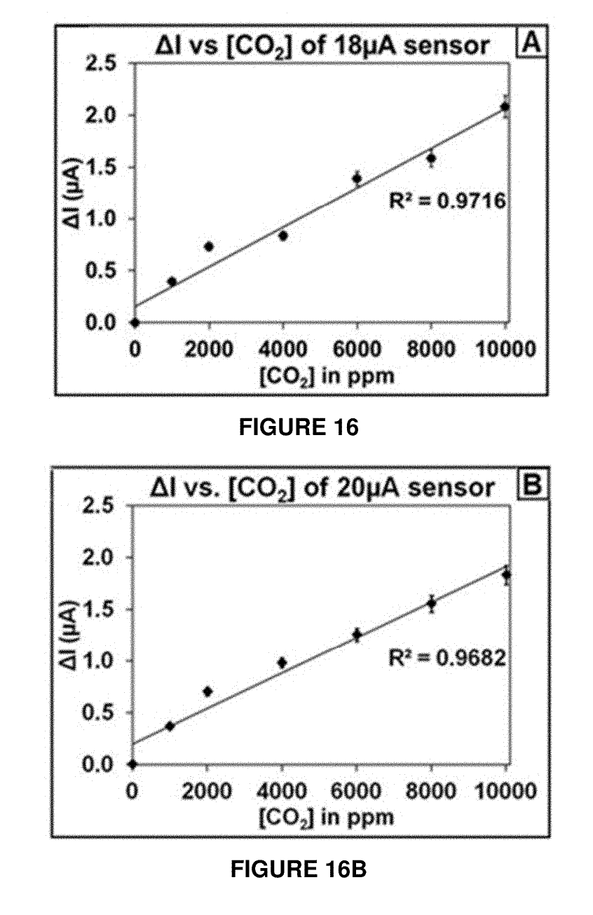

Through customization of polymer nanowires or carbon nanotubes by chemical synthesis, a nanowire or carbon nanotube sensor for detecting the environmental and subsurface CO₂ has been developed. The customized nanowire or carbon nanotube sensors detect CO₂ reversibly in the 0 ppm to 10,000 ppm range (FIG. 16) with response time of 2 minutes and reversing within 30 minutes in the temperature range of 10° C. to 60° C. and over 0% to 80% relative humidity. Using a DC intensity measurement system, CO₂ concentrations as low as 25 ppm were detected.

Polymer Nanowires Formation.

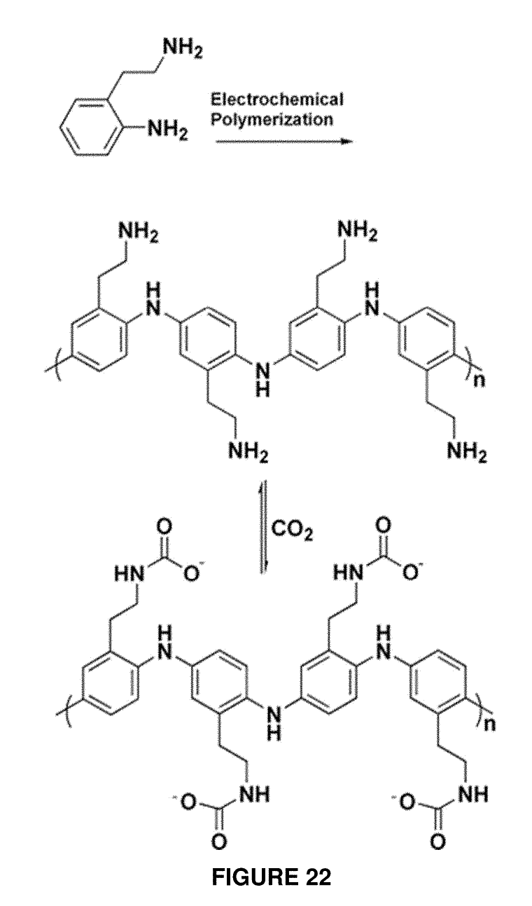

Alkyl amine-modified polymer nanowires for selective and sensitive CO₂ detection were prepared. First, alkylamine functionalized aniline monomer was synthesized by chemical reactions and this monomer was used to create alkyl amine-modified polymer nanowires using template-free electrochemical method. The chemical structure and its interaction with CO₂ are shown in FIG. 22. The formation of the carbonate upon CO₂ interactions with the amine groups of the nanowire imparts this selectivity. To the best of the applicants' knowledge, the amine-modified aniline monomer is a unique compound. The formation of the carbonate is a reversible reaction. Thus, the sensor is reversible and can detect both increases and decreases in CO₂ levels.

In addition, the novel growth process of creating polymer nanowires disclosed herein is unique. Six different electrolyte systems (formic acid, acetic acid, perchloric acid, hydrochloric acid, phosphoric acid and nitric acid) have been investigated with varying concentrations (0.2-1.0 M) in deionized water for the growth of polymer nanowires using three-step electrochemical method. These electrolytes offer specific counter ions, ionic strength, polarity, and acid strength (pKa) that play a critical role during nanowire growth.

Initial attempts to grow polymer nanowires were conducted using formic acid (HCOOH) at room temperature. Solutions of 0.2 M aniline (monomer) in 0.8 and 1.0 M HCOOH were prepared. Using the 1.0 M HCOOH solution, after the electro-polymerization process was completed, the Si chip devices were examined under a microscope with 45× magnification. The visual examination showed no growth and the device appeared to be unchanged from what it was before the electrochemical process. This was confirmed by current-voltage (I-V) characteristic measurements. The same results were obtained for the 0.8 M solution of HCOOH so lower concentrations were not attempted. The same results were observed when using acetic acid (CH₃COOH). The conclusion was that organic acids in general are poor electrolytes for the electrochemical growth of polymer nanowires.

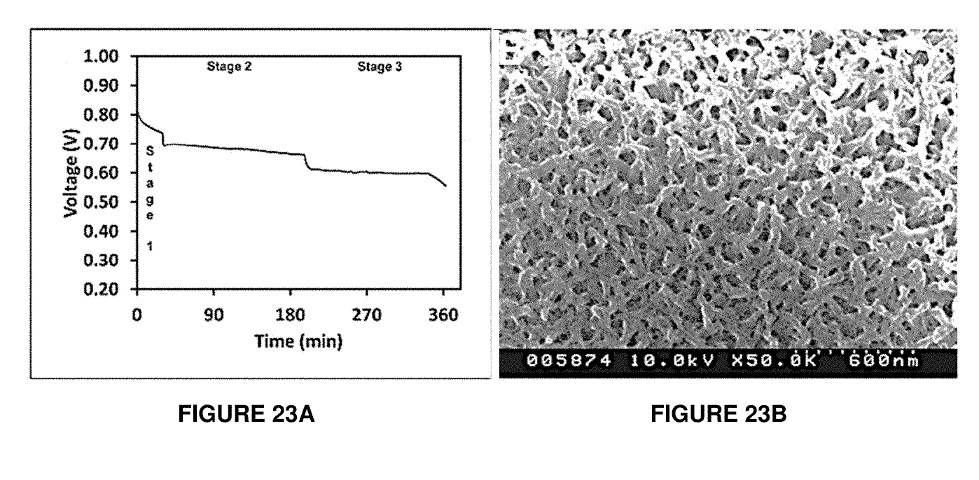

All five concentrations (0.2 M, 0.4 M, 0.6 M, 0.8 M and 1.0 M) of perchloric acid (HClO₄) showed varying degrees of growth. All four concentrations of HCl and HNO₃ electrolyte solutions (0.2 M, 0.4 M, 0.6 M and 0.8 M) showed varying degrees of growth. All of the inorganic acids resulted in successfully grown polymer nanowires (˜50-150 nm diameter and ≥2 μm length) in the concentration range (0.2-0.6 M) in various degrees. In particular, 0.2 M aniline monomer in 0.4 M HNO₃ electrolyte solution produced best polymer nanowires with a porous nano-network, spanning the gap and connecting the metal electrodes, as shown in FIG. 23.

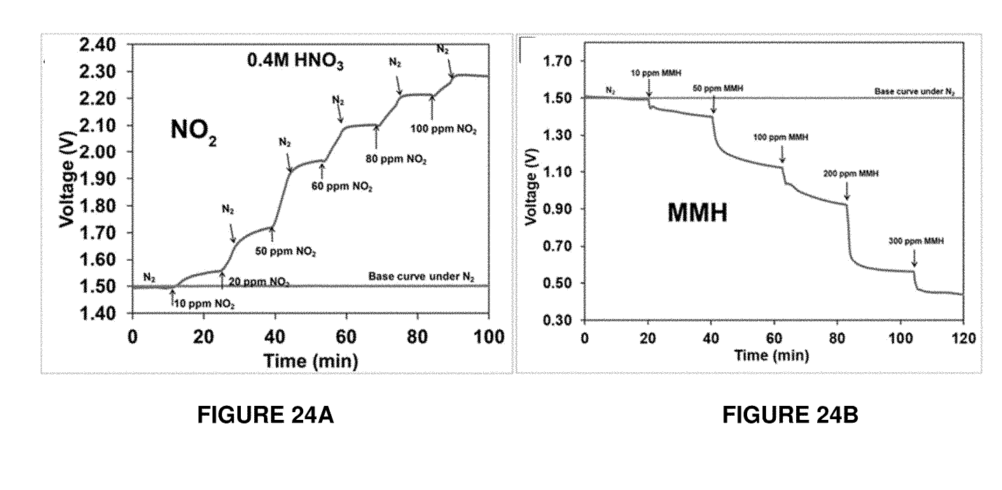

Polymer-nanowires sensor devices fabricated using the above mentioned inorganic acids including HNO₃ electrolyte solution were tested by exposing to analyte gases such as toxic nitrogen dioxide (NO₂) and monomethyl hydrazine (MMH) and their performance was evaluated. The Polymer-nanowires sensor devices grown with 0.2 M aniline monomer in 0.4 M HNO₃ electrolyte solution showed very sensitive and significant responses to six different concentrations of NO₂ (FIG. 24A) and also to MMH (FIG. 24B). Even at high concentrations, the device showed a clear difference in response compared to a closest concentration exposed.

Based on an evaluation of all the PNMDs from these different inorganic acid sources, all the acids that produced devices are responsive to analyte molecules/gases to some extent. But in terms of magnitude of response, sensitivity and stability during testing the 0.2 M aniline in 0.6 M HNO₃ electrolyte solution-based sensor devices appear to be the best with 0.2M to 0.4M HNO₃ electrolyte solution being preferred for the growth of these amine functionalized polyaniline nanowires.

Both the electrolyte system and its concentration were optimized to achieve high quality polymer nanowires with diameters ranging from 30 nm to 150 nm, length ≥2 μm with a highly porous nano-network morphology, resulting in high surface area, highly reactive sites and enhanced response and sensitivity for detecting CO₂.

The concentration effect of amine functionalized aniline monomer (0.1-1.0 M) was investigated in an electrolyte system (0.4-0.6 M nitric acid). The optimized monomer concentration was found to be 0.2-0.4 M in a nitric acid (0.4-0.6 M) electrolyte system to obtain the above mentioned high quality polymer nanowires.

The quality of polymer nanowires was further optimized by applying very low-level current (12-50 nanoampere) and slow growth mechanism over a period of time (4-6 hours). The high-quality polymer nanowires obtained in this process mentioned above were confirmed by scanning electron microscope (SEM) analysis, current-voltage (I-V) measurements and evaluating CO₂ sensor performance. This novel process was used for the fabrication of other sensors.

Fabrication of Carbon Nanotubes (CNT) Biosensors—

A 3% carboxylic acid-functionalized single-wall CNT solution was prepared in several different concentrations—
(a) 0.1 mg/mL comprising 10 mL DMF+1 mg CNT (aliquot 1 mL per vial for single use),
(b) 0.075 mg/mL comprising 5 mL DMF+1 mL of (a) above (0.1 mg/mL),
(c) 0.05 mg/mL comprising 10 mL DMF+1 mL of (a) above (0.1 mg/mL), and
(d) 0.025 mg/mL comprising: 10 mL DMF+0.5 mL of (a) above (0.05 mg/mL).
   Each sample was sonicated for ˜30 min prior to use to eliminate aggregates.

The electrode arrangement as described above was connected to a function generator and oscilloscope set to deliver 1.5 MHz at 2V for dielectrophoretic alignment of CNTs in the 2-micron gap between two metal electrodes mounted on the substrate and 20 μL of CNT solution was placed into the gap of the device.

The device was connected to the function generator and voltage was applied for 30-120 seconds (selected as necessary to deposit CNTs bridging the device gap) followed by rinsing with deionized (DI) water to remove excess DMF and the device was allowed to dry completely at RT. Alternatively, a clean absorbent wipe can be applied to the edge of the device to wick the DMF from each device and then the device was air dried at room temperature.

As a quick check if sufficient CNTs were deposited, the electrical resistance of the dried device was determined using a multimeter.

The devices with CNTs spanning the gap were then anneal in a closed oven at 200-250° C. for 1 hour followed by cooling for about 30 minutes to reach ambient temp.

I-V curves across the device were then generated. An increase in current when compared to the non-annealed device should have resulted as a result of CNTs contacting the gold electrodes now being annealed to the surface.

A PBASE solution comprising of 1.5 mL of 6 mM PBASE (MW=385.41 g/mol) and 20 mL of DMF=46.25 mg 5 mM PBASE was prepared, covered by foil (because PBASE is light sensitive) and stored at −25° C.

The device was then placed in 2-3 mL of the PBASE solution for 30 min at RT in the dark, followed by washing with MilliQ™ H₂O (the H₂O was autoclaved and neutralized prior to use as PBASE has a tendency to bind and react with many contaminants) incubation for 5-10 min (or until the devices are completely dry) at the very minimum at 40° C. I-V measured across the device again should start to a current decrease.

Antibody and antigen samples in appropriate media were then prepared 4 μL of a selected antibody solution was placed on top of the gold electrodes of each device and incubate at 37.5-40° C. for up to 60 minutes (or until completely dry, which is about 20-25 min)

Measure the I-V characteristics.

Passivation buffer solutions were prepared comprising:
1. 0.1% Tween 20=500 μL Tween 20+499.5 mL MiiliQ H₂O,
2. 6 mM 6-Mercapto-1-hexanol (MCH) (MW=134.24 g/mol; d=0.981 g/mL)=410 uL MCH+500 mL MilliQ H₂O, or
6 mM MCH=82.10 uL MCH+99.92 mL MilliQ H₂O, and
3. 0.1 mM Ethanolamine (EA)=1.5 mL EA+498.5 mL MilliQ H₂O.

The device was submerged in 0.1 mM EA for 30 min at RT, then in 0.1% Tween 20 for 30 min at RT followed by submerging in 6 mM MCH for 1 hr at RT. The passivated device was then rinsed with MilliQ H₂O and dried using a Kim Wipe™ and/or air dried at RT for 1 hr.

If not used immediately the passivated devices should be wrapped in parafilm and foil and stored at −25° C.

Before using the CNT Biosensor as a detection testing, the I-V properties of the passivated device should be determined to provide a base curve. To use the sensor a diluted mixture of antigen/media is applied to the sensor and the sensor is incubated for at least 20 minutes at 37.5-40° C. until dry followed by determining the I-V characteristics of the treated sensor. This can be repeated using different concentrations of the antigen/media.

Detection of Disease Biomarkers.

The sensors described herein can also be used for detection of disease biomarkers. Referring to FIG. 9A, a general schematic for a biosensor 1000 for use in diagnostics with an on/off switch 998 is shown. A nanowire biosensor chip array 1002 (FIG. 9B) has mounted thereon a standardized biosensor chip 1004 which includes one or more nanowire biosensor array chips 1006 mounted on a card with electrical contacts. Each of the chips can be designated for detection of a different disease biomarker (for an expanded survey of tests for, e.g. cancers, Alzheimer's (see below), Parkinson's, Hepatitis, Cardiac disease, etc.) or each of the chips can be designated for the same disease biomarker (for additional accuracy). The card is then inserted into the hand-held device shown in FIG. 9A connecting the electrical contacts 1008 to mating contacts in the biosensor 1000 for analysis of the data collected from the biosensor chips and card.

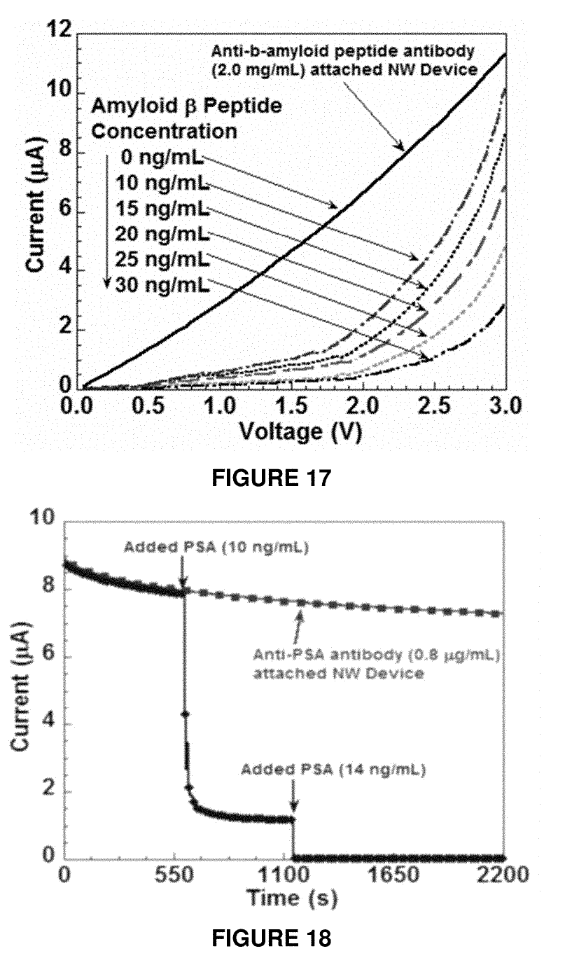

Another preferred embodiment is a porous polymer nanowire or carbon nanotube platform-based sensor for early diagnosis of Alzheimer's disease (AD) by detecting AD-associated biomarkers. Conducting polymers or carbon nanotubes modified with covalently attached antibodies specific to different AD biomarkers such as different forms of Aβ (monomers and oligomers) as capture and transducing agents for an electrochemical-based biosensor were used in the sensor. Nanowire or nanotube devices detect 36 pM for the Aβ oligomer and sub-pM for the Aβ monomer. This is approximately three orders of magnitude better than what can be achieved using the same antibodies in enzyme-linked immunosorbent assay (ELISA) or blot tests for Aβ detection (1-10 nM). Antibodies are attached to nanowires or nanotubes via amide coupling using N-hydroxysuccinimide. Standard current-voltage (I-V) curves were obtained when the anti-Aβ42 sensors were tested with a semiconductor parameter analyzer. FIG. 17 shows the I-V curves of an anti-Aβ42 peptide antibody-attached sensor exposed to varying concentrations of Aβ42 in phosphate buffered saline (PBS) solution for 5 min. at each concentration. A significant change in the I-V curve of the anti-Aβ42 peptide antibody-attached sensor was observed after successive exposures of Aβ42. All sensors responded to the introduction of Aβ, as expected. This antibody-based nanowire or nanotube sensor exhibited much higher sensitivity than the ELISA and Western-blot tests.

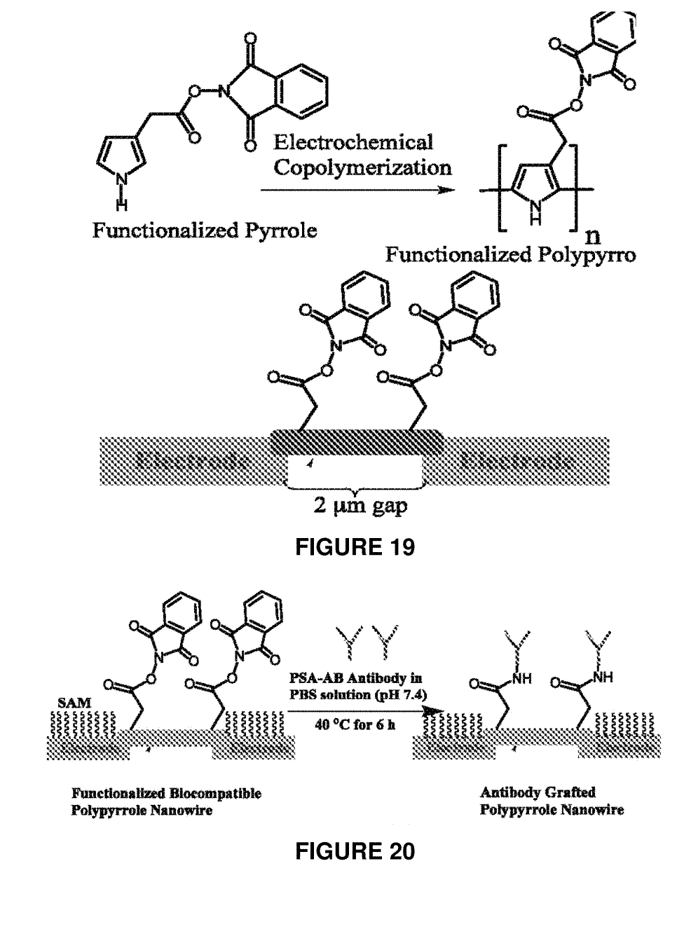

Referring now to FIG. 19, for the development of biosensors to detect Alzheimer's disease (AD) or cancers, N-hydroxyphathalo-succinimide or N-hydroxysuccinimide functionalized pyrrole monomer was synthesized and created N-hydroxyphathalo-succinimide or N-hydroxysuccinimide functionalized polypyrrole nanowires by electrochemical method. FIG. 20 illustrates and antibody conjugation followed the above synthesis.

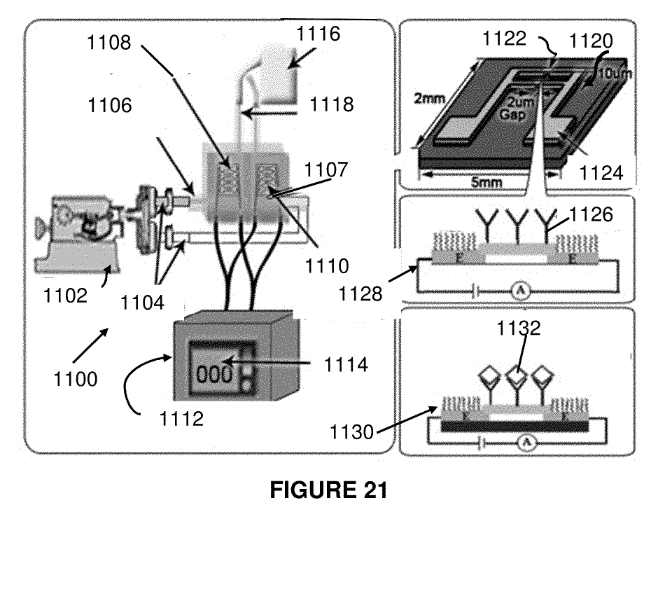

FIG. 21 is a schematic diagram showing a testing device with enlarged views illustrating a polymer nanowire assembly with an PSA-AB antibody attached and the interaction of the antibody with corresponding disease biomarker antigen or protein for detecting disease. The testing device 1100 includes a pump 1102 connected delivery syringes 1104 which feeds a test sample through a sample inlet 1106 into a test unit 1107 containing a sample device (PNEBD) 1108 and a reference device (PNEBD) 1110. The sample device 1108 and the reference device 1110 are connected to a signal processing control unit 1112 which has a display 1114 for showing results of the test. Waste sample material exiting the test device 1107 is passed through a scrubber 1116 to a waste outlet 1118. Also shown is an enlarged view of a chip device 1120 which includes a conducting polymer nanowire 1122 between left and right connecting pads 1124. The same construction chip device 1120 is used for both the sample device (PNEBD) 1108 and the reference device (PNEBD) 1110 with the difference being that the sample device (PNEBD) 1108 is labeled with PSA-AB antibody 1126 as schematically shown in first and second further enlarged views 1128, 1130, the second further enlarged view 1130 schematically illustrating attachment of a PSA antigen 1132 after incubation at room temperature for 2 hours.

A polymer nanowire or carbon nanotube sensor device for the detection of prostate cancer biomarker PSA (prostate specific antigen) is another preferred embodiment. The response time of nanowire- or nanotube-based sensors was evaluated by detecting current changes as a function of time. FIG. 18 shows the current vs. time response for a nanowire or nanotube sensor functionalized with anti-PSA antibodies that was exposed to a constant bias of 2.5 V. A much more significant change in current was observed when small concentrations of the antigen were added. In all cases, the response was observed and stabilized within a few minutes.

Using the procedures described above, sensors were characterized and tested and their performance, such as response, sensitivity, selectivity and reproducibility for the detection of toxic metals in phosphate saline buffer solution (PBS) and biofluids (urine, saliva) and detection of disease biomarkers (proteins) in PBS, artificial cerebral spinal fluid (aCSF) and clinical CSF media were evaluated

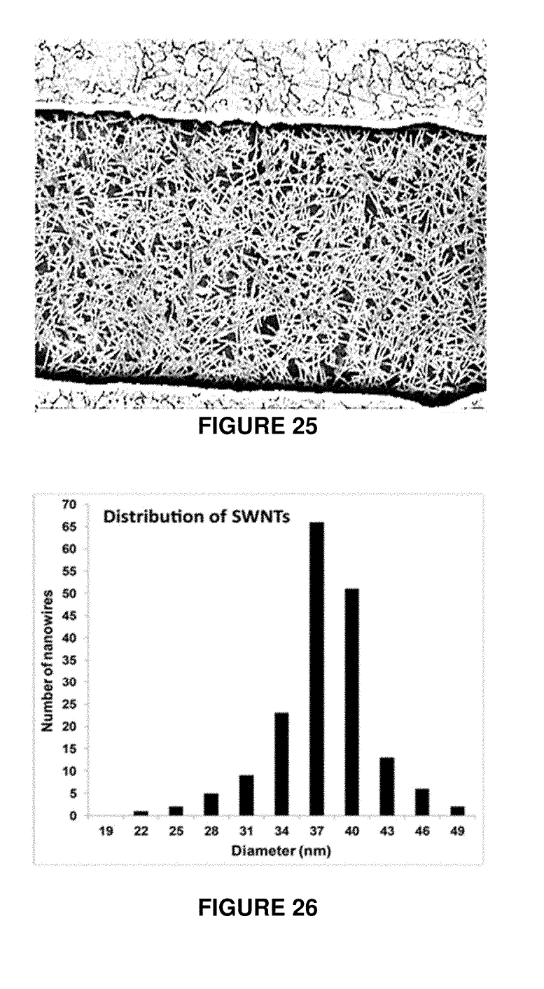

Single-wall CNTs with an average diameter of 37 nm spanning the 2 μm gap of the microelectronic Si-chip sensor devices were produced. FIG. 25 is a scanning electron microscope (SEM) image of the CNTs within the 2 μm gap of a microelectrode in a sensor device produced according to the procedures described herein. FIG. 26 is a histogram of the diameters of the CNTs shown in FIG. 25. The single-wall carbon nanotubes (SWNTs) allow any applied current to pass across a gap. The changes in the current passing across the SWNT are the basis of detecting target biomolecules, toxic heavy metal-ions or other toxic/cancerogenic chemicals. The protocols set forth herein provided superior sensor fabrication yield and reproducibility.

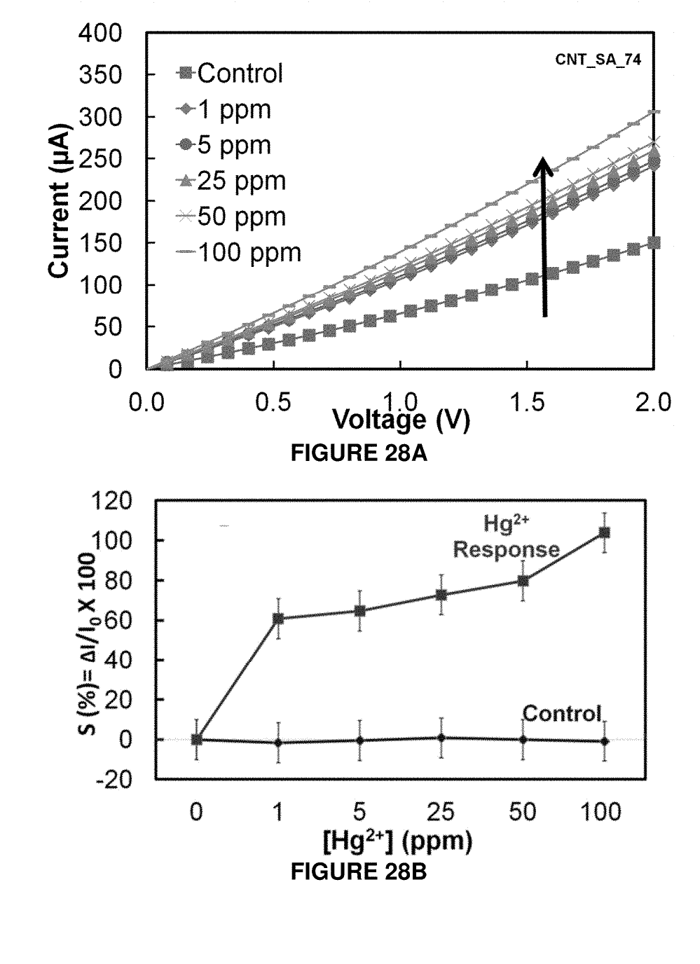

The performance of mercury sensors produced as described herein were tested and evaluated for detecting the presence of mercury (Hg²⁺) ions in water, urine and saliva. FIG. 28 shows the measured I-V curves of a representative mercury sensor device. The acquired I-V curves show an upward trend in current when the device was exposed to varying concentrations of Hg²⁺ ions. The derived calibration curve (percent response versus Hg²⁺ ion concentration; FIG. 28B) of the device also shows the upward trend in response with increasing concentration of Hg²⁺ ion. The sensor showed a significant response compared to its control counterpart. The observed response was approximately 70.0±3.5% at 1 ppm and 103.0±5.2% at 100 ppm. A t-test was conducted and the p-value with α=0.05 and obtained p=0.006 was calculated. Based on the p-value, it can be concluded that the results were statistically significant.

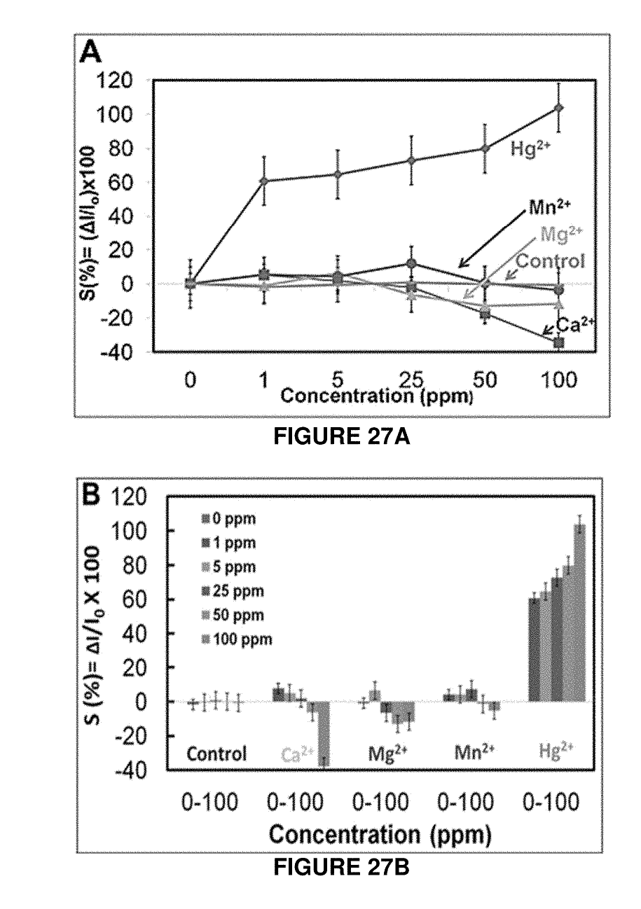

Mercury sensor responses were tested and evaluated with different interfering ions in water to establish its sensitivity and specificity toward Hg²⁺ ions. The sensor responses for calcium (Ca²⁺), manganese (Mn²⁺), magnesium (Mg²⁺), mercury (Hg²⁺) and a control in water are shown in FIGS. 27A and B. These results show that the device response for Hg²⁺ ions is significantly stronger than the response to the interfering ions. The overall response for Hg²⁺ ions is 100× stronger (an average p<0.01 by t-test) than the average maximum response for the interfering ions at 100 ppm. This comparison suggests that our mercury sensor is relatively specific and sensitive to Hg²⁺ ions compared to the other ions in water.

Multiplex array-based biosensor devices (proteins) were also fabricated and demonstrated the capability of detecting Alzheimer's Disease (AD) associated biomarkers in PBS, artificial cerebral spinal fluid (aCSF) and cerebral spinal fluid (CSF) samples. After nanowire growth and surface passivation, the devices were conjugated to commercial AD-specific antibodies (Abs) such as amyloid beta 1-42 (Aβ1-42), tau and p-tau Abs. The biosensor response to each AD biomarker was evaluated using 4 or 5 devices.

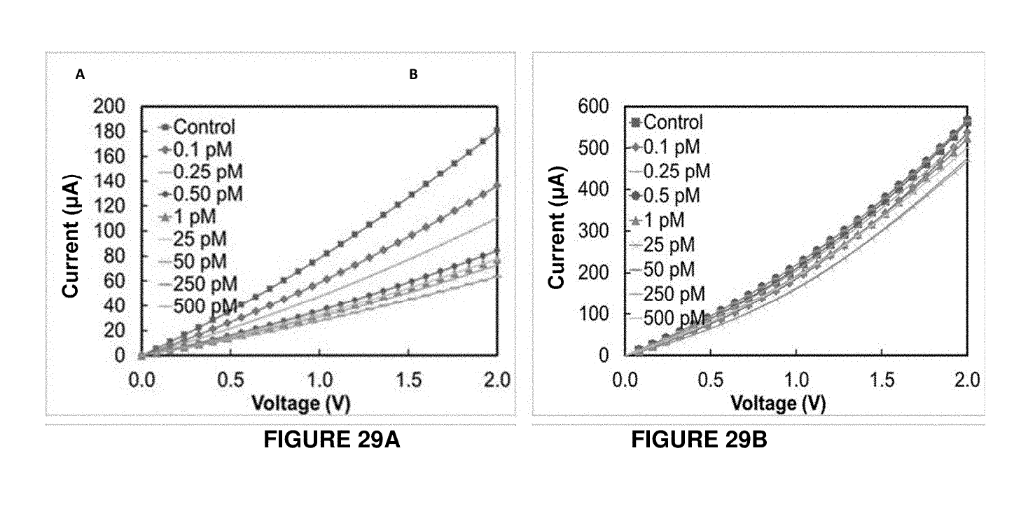

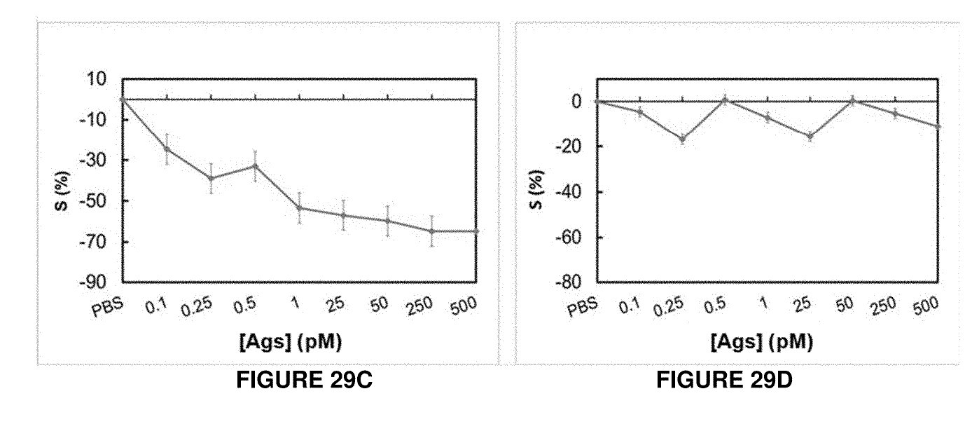

FIGS. 29A-D show the response of biosensor devices conjugated to Aβ1-42 Abs and exposed to AD biomarker antigen (Ag) Aβ 1-42 in PBS. The I-V curves show the current-voltage profile of Nanowire Sensor Array-based Assay for Early Diagnosis of Alzheimer's Disease (Adnos) devices conjugated with Aβ1-42 Ab and exposed to varying concentrations of Aβ1-42 Ag in 1×PBS (pH 7.4 at room temperature) in increasing order of concentration starting from 100 femtomolar (fM) to 500 picomolar (pM). A clear and significant decrease in current compared to the first exposure with no Ag (control) was noted. The sensors consistently responded to each concentration studied with a successive decrease in current as the concentration of the Aβ1-42 antigen (Ag) increased. This indicated that the devices were consistently sensitive to AD-specific biomarkers in the femtomolar to the picomolar range. The biosensor device responded by showing a downward trend in current response of −21±1.05% at 100 fM Ag which decreased sequentially to −63±3.15% at 500 pM Ag in PBS. The I-V curve (FIG. 29B) shows a control device with no antibodies (Abs) conjugated to polymer nanowires. There is almost no clear response trend when exposed to the serially diluted Ag in PBS. The biosensor devices showed a statistically significant response of 0.002 p value as depicted by t-test. The concentration range of 50 to 110 pM is significant because the clinically relevant concentrations of the widely accepted Aβ biomarkers are encompassed within this range.

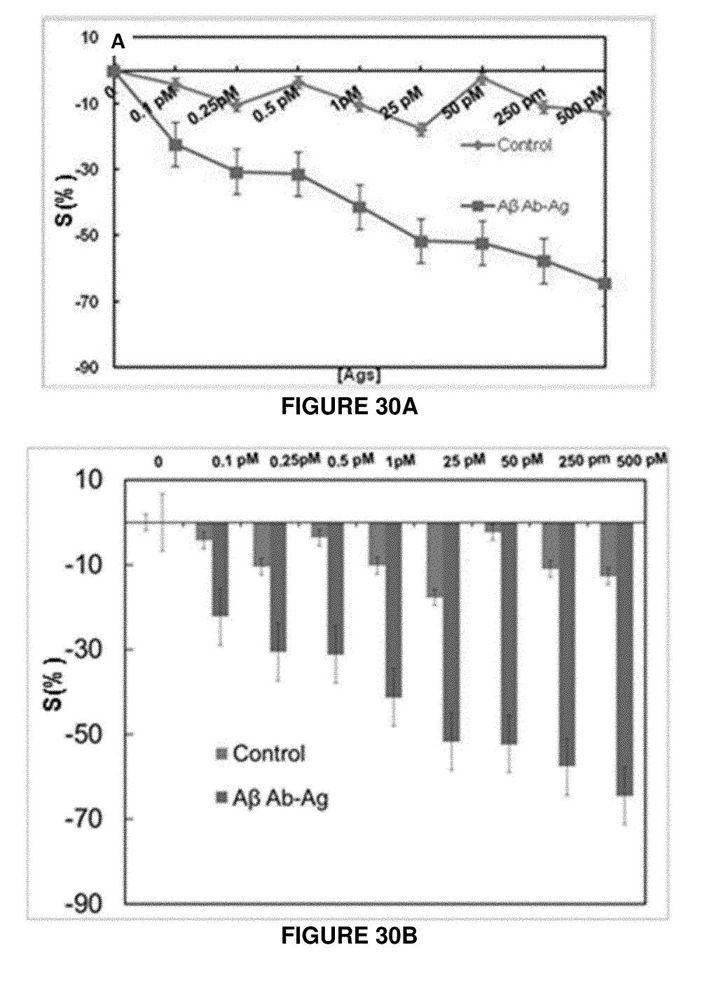

FIGS. 30A and B show the calibration curve derived from the I-V curve showing the response of the biosensor devices compared to the controls. The lower line in FIG. 30A and the longer bars in FIG. 30B shows the average response of multiple biosensor devices conjugated with Aβ1-42 Ab. The other curved line and bars show the response of control devices where the nanowires have no Abs conjugated to them. The response at each concentration of Ag is significantly different from the controls. At 100 fM of Aβ1-42 peptide antigen, the average response of the biosensor devices was −22±1.1% and at 500 pM the response decreased to −66±3.3%. The control devices showed a response of −4±0.2% at 100 fM of Ag with no clear decrease in current response. At 500 pM, it was −12±0.6%. The response between control and response was statistically significant with a p value <0.001 as determined by t-test.

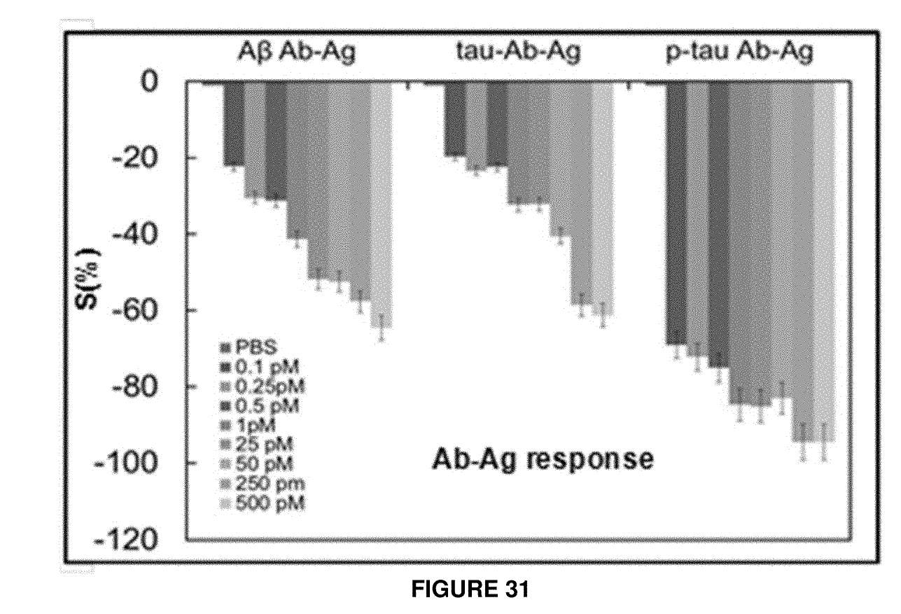

The response of tau and p-tau Abs conjugated biosensor devices was also tested and evaluated. The devices were exposed to a similar serial dilution of tau and p-tau Ag. The same downward trend in current compared to controls was observed. FIG. 31 summarizes the response of biosensor devices to each pair of Ab-Ag interaction. Average response from each pair of Ab-Ag interaction was calculated using 6 to 7 devices. Devices conjugated with Aβ1-42, tau or p-tau Abs were exposed to their corresponding Ag. The downward trend in current was seen with increases in corresponding Ag concentrations. In the case of Aβ1-42 Ab-Ag response, the response was almost linear from 100 fM to 500 pM. In the case of tau Ab-Ag response the downward current response was seen, but the response did not show any linearity between 100 fM and 500 fM. The current response further decreased at 500 pM. The highest response was seen in case of p-tau Ab-Ag in which, at 100 fM of p-tau peptide antigen, the response of the Adnos devices were −69±3.45% and at 500 pM the response decreased to −94±4.7%. In each case of Aβ1-42 Ag response, the difference was statistically significant as determined by t-test where p value=<0.005. Additionally, the sensor signals increased distinctly in the concentration regime from 50 to 110 pM. This concentration range is critical because the clinically relevant concentrations of the known Aβ biomarkers are encompassed within this range. In the particular case of p-tau Ab-Ag, the response at 100 fM was a sharp negative trend and the response appeared to plateau from 25 pM to 500 pM. This could be because the Abs was already saturated due to the Ab-Ag interaction, an aspect we intend to optimize in our future efforts.

Template-free, site-specific electrochemical approaches to the precise fabrication of individually addressable polymer nanowire or carbon nanotube microelectronic electrode junction devices have been demonstrated. A variety of different polymer nanowires or carbon nanotubes can be incorporated into an array format by electrochemically attaching to each individual junction a particular electroactive monomer. For example, a list of preferable nanomaterials for different sensors is set forth in Table 1 below:

TABLE 1

| Sensor | Nanomaterials | Additional preferable |
|---|---|---|
| Type | currently in use | nanomaterials |
| CO₂ Sensor | Amine functionalized | Amine functionalized |
| | polymer nanowires | carbon nanotubes |
| NO₂ and | Functionalized polyaniline | Modified single wall |
| MMH | nanowires | carbon nanotubes |
| Sensors | | |
| Alzheimer's | N-Hydroxy succinimide | N-Hydroxy succinimide |
| Disease | functionalized polymer | functionalized single wall |
| (AD) Sensor | nanowires followed by | carbon nanotubes followed |
| | conjugation with AD | by conjugation with AD |
| | proteins and biomarkers | proteins and biomarkers |

It is demonstrated herein that the excellent performance of the modular nanowire or nanotube microelectronic sensors in terms of their high sensitivity and their fast response for detecting toxic chemicals, gases and biomarkers are useful. These results demonstrate the versatility of modular nanowires or nanotubes microelectronic sensor technology for chemical and biological sensor applications.

Various modifications and alterations of the invention will become apparent to those skilled in the art without departing from the spirit and scope of the invention, which is defined by the accompanying claims. It should be noted that steps recited in any method claims below do not necessarily need to be performed in the order that they are recited. Those of ordinary skill in the art will recognize variations in performing the steps from the order in which they are recited. In addition, the lack of mention or discussion of a feature, step, or component provides the basis for claims where the absent feature or component is excluded by way of a proviso or similar claim language.

While various embodiments of the present invention have been described above, it should be understood that they have been presented by way of example only, and not of limitation. Likewise, the various diagrams may depict an example architectural or other configuration for the invention, which is done to aid in understanding the features and functionality that may be included in the invention. The invention is not restricted to the illustrated example architectures or configurations, but the desired features may be implemented using a variety of alternative architectures and configurations. Indeed, it will be apparent to one of skill in the art how alternative functional, logical or physical partitioning and configurations may be implemented to implement the desired features of the present invention. Also, a multitude of different constituent module names other than those depicted herein may be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead may be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or claimed in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether flow control or other components, may be combined in a single package or separately maintained and may further be distributed across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives may be implemented without confinement to the illustrated examples. For example, block diagrams and their accompanying description should not be construed as mandating a particular architecture or configuration.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A method of producing a sensor comprising
forming a first and a second noble metal electrode on a silicon substrate, said electrodes separated by a gap of 0.5 to 4.0 μm, said electrodes connected to a power source and means for measuring current and/or voltage between the first and second noble metal electrodes.
forming a nano-network of functionalized nanowires or nanotubes in situ, the network of nanowires or nanotubes spanning the gap and providing an electrically conductive pathway connecting the first and second noble metal electrodes.

2. The method of claim 1 wherein the sensor is a carbon dioxide sensor and wherein the nano-network is formed by the in-situ polymerization of an amine functionalized aniline monomer to form amine functionalized aniline polymer nanowires spanning the gap; and
using an electrochemical process, forming a nano-network of alkyl amine-modified polymer nanowires.

3. The method of claim 2 wherein the electrochemical process uses 0.1-1.0 M of an electrolyte in water, the electrolyte selected from the group consisting of formic acid, acetic acid, perchloric acid, hydrochloric acid, phosphoric acid and nitric acid in water.

4. The method of claim 3 wherein the electrolyte is 0.4-0.6 M nitric acid and the nano-network is formed from amine functionalized aniline monomers.

5. The method of claim 2 wherein the electrochemical process uses an electrical current of 12-50 nanoampere for a period of 4-6 hours.

6. The method of claim 2 wherein the nanowires have a diameter of 30 nm to 150 nm.

7. The method of claim 1 wherein the sensor detects the presence of one or more of a disease biomarker indicating the existence of cancer, hepatitis or Alzheimer's, Parkinson's or cardiac disease, wherein the nano-network is formed by the in-situ polymerization of a monomer to form amine functionalized polymer nanowires spanning the gap and covalently attaching to the amine-modified polymer nanowires or nanotubes Aβ (amyloid β) monomers or oligomers.

8. The method of claim 7 for formation of a sensor for Alzheimer's or cancer detection wherein the nanowires comprise electrochemically formed N-hydroxyphathalo-succinimide or functionalized N-hydroxyphathalo-succinimide polypyrrole nanowires with antibodies specific to Alzheimer's or cancer-specific proteins or biomarkers conjugated to said polypyrrole nanowires.

9. The method of claim 1 wherein the sensor is formed from functionalized carbon nano-tubes.

10. The method of claim 7 wherein the sensor formed is for the detection of Alzheimer's or cancer comprising carbon nanotubes functionalized by electrochemically depositing N-hydroxyphathalo-succinimide or functionalized N-hydroxyphathalo-succinimide on the surface of the nanotubes, with antibodies specific to Alzheimer's or cancer specific proteins or biomarkers conjugated to said functionalized nanowires.

11. The method of claim 9 wherein the carbon nano-tubes are functionalized with carboxylic acid and the sensor detects the presence of mercury.
